(19) United States
(12) Patent Application Publication
(10) Pub. No.: US 2016/0064409 A1
(43) Pub. Date: Mar. 3, 2016

(54) NON-VOLATILE SEMICONDUCTOR STORAGE DEVICE

(71) Applicant: KABUSHIKI KAISHA TOSHIBA, Tokyo (JP)

(72) Inventor: Toshitake YAEGASHI, Yokohama kanagawa (JP)

(21) Appl. No.: 14/811,660

(22) Filed: Jul. 28, 2015

Related U.S. Application Data
(60) Provisional application No. 62/043,812, filed on Aug. 29, 2014.

(51) Int. Cl. H01L 27/115; H01L 29/423; H01L 21/28; H01L 29/51

(52) U.S. Cl. CPC H01L 27/11582; H01L 29/511; H01L 29/518; H01L 29/42348; H01L 29/42364; H01L 21/28282

(57) ABSTRACT

A non-volatile semiconductor storage device includes a plurality of gate electrodes stacked in a first direction, a channel portion facing the gate electrodes and extending in the first direction, and first and second charge storage layers between the gate electrode and the channel portion in a second direction crossing the first direction, wherein the second charge storage layer has portions that are between the gate electrodes in the first direction.

### CROSS-REFERENCE TO RELATED APPLICATION

This application is based upon and claims the benefit of priority from U.S. Provisional Patent Application No. 62/043,812, filed Aug. 29, 2014, the entire contents of which are incorporated herein by reference.

### FIELD

Embodiments of the present disclosure relate to a non-volatile semiconductor storage device.

### BACKGROUND

A NAND-type flash memory device is an example of a non-volatile semiconductor storage device. To enlarge a capacity and to reduce an area of cells in the NAND-type flash memory device, there has been proposed a 3D-NAND-type flash memory device where memory cells are stacked on a printed circuit board in a vertical direction. One such 3D-NAND-type flash memory device employs a charge trapping film in a memory cell.

### BRIEF DESCRIPTION OF THE DRAWINGS

FIG. 1 is a view schematically showing the configuration of a memory cell block of a 3D-NAND-type flash memory device according to an embodiment.

FIG. 2 is a perspective view showing the configuration of a part of a memory cell region of the 3D-NAND-type flash memory device according to the embodiment.

FIG. 3 is a view of a cross-section taken along line 3-3 in FIG. 2.

FIG. 4 is an enlarged view of a region R in FIG. 3.

FIG. 5 to FIG. 8 are cross-sectional views that show a manufacturing method of the 3D-NAND-type flash memory device according to the embodiment.

FIG. 9 is a cross-sectional view that shows the structure and a manufacturing method of a 3D-NAND-type flash memory device according to another embodiment.

### DETAILED DESCRIPTION

A non-volatile semiconductor storage device according to an embodiment includes a plurality of gate electrodes stacked in a first direction, a channel portion facing the gate electrodes and extending in the first direction, and first and second charge storage layers between the gate electrodes and the channel portion in a second direction crossing the first direction, wherein the second charge storage layer has portions that are between the gate electrodes in the first direction.

### First Embodiment

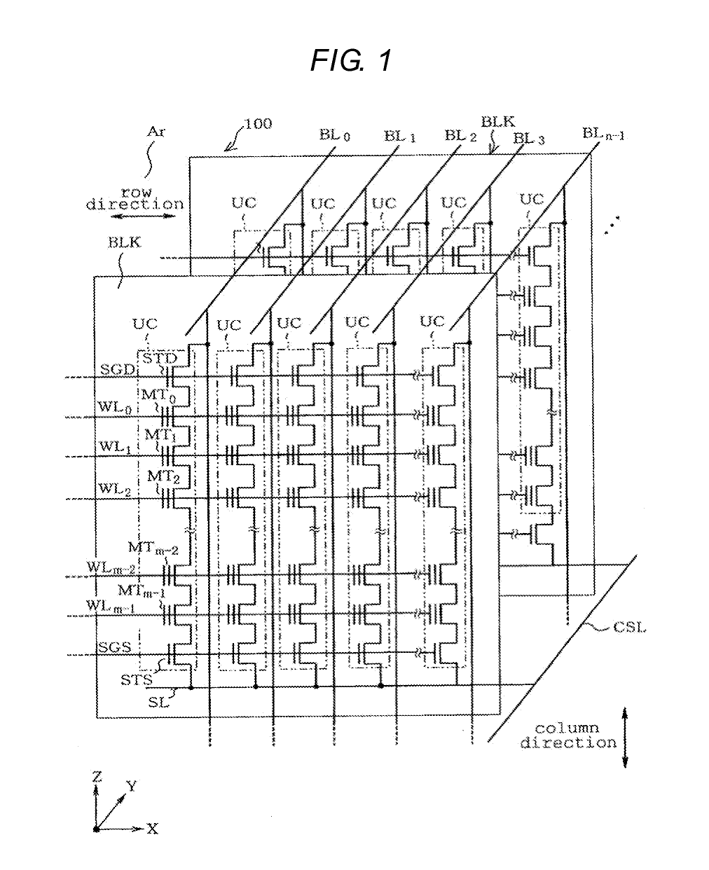

Hereinafter, the first embodiment of the present disclosure which provides a 3D-NAND-type flash memory device as example of a non-volatile semiconductor storage device, is explained with reference to FIG. 1 to FIG. 8. In the explanation made hereinafter, elements which have identical functions and identical configurations are given the same symbol. The drawings provide schematic views and hence, the relationship between a thickness and a planar size, a ratio between thicknesses of respective layers and the like do not always match the actual ones used in the non-volatile semiconductor storage device. Upper, lower, left and right directions also indicate relative directions in the case where a circuit forming surface side of a semiconductor substrate is set as an upper side, and these directions do not always match directions set with reference to the direction of gravitational acceleration.

In the explanation made hereinafter, for the sake of convenience of the explanation, an XYZ orthogonal coordinate system is used. In this coordinate system, two directions which are directions parallel to a surface of the semiconductor substrate and are orthogonal to each other are set as an X direction and a Y direction, the direction along which word lines WL extend is set as the X direction, and the direction which is orthogonal to the X direction and along which bit lines BL extend is set as the Y direction. The direction which is orthogonal to both the X direction and the Y direction is set as the Z direction. The explanation of the embodiment is made by focusing on the NAND-type flash memory device which is one example of the non-volatile semiconductor storage device, and other techniques and types of non-volatile semiconductor storage device are referenced as needed.

FIG. 1 illustrates a view schematically showing the configuration of a memory cell block BLK of a 3D-NAND-type flash memory device 100. As shown in FIG. 1, the 3D-NAND-type flash memory device 100 includes a memory cell array Ar where a large number of memory cells are disposed in a matrix configuration. The memory cell array Ar includes a plurality of memory cell blocks BLK.

A plurality of unit memory cells UC are disposed in each memory cell block BLK. In the unit memory cell UC, selection gate transistors STD are provided on a side connected to bit lines BL₀ to BLₙ₋₁, and selection gate transistors STS are provided on a source line SL side. A total of m (m=2^{k}, for example) memory cell transistors MT₀ to MTₘ₋₁ are connected in series between the selection gate transistor STD and the selection gate transistor STS.

The plurality of unit memory cells UC form the memory cell block BLK, and the plurality of memory cell blocks BLK form the memory cell array Ar. That is, in one memory cell block BLK, the unit memory cells UC are disposed in parallel in n rows along the row direction (lateral direction or X direction in FIG. 1). In the memory cell array Ar, the plurality of memory blocks BLK are disposed along the Y direction in FIG. 1.

A control line SGD is connected to gates of selection gate transistors STD. The word line WLₘ₋₁ is connected to control gates of m-th memory cell transistors MTₘ₋₁ connected to the bit lines BL₀ to BLₙ₋₁. The word line WL₂ is connected to control gates of third memory cell transistors MT₂ connected to the bit lines BL₀ to BLₙ₋₁. The word line WL₁ is connected to control gates of second memory cell transistors MT₀ connected to the bit lines BL₀ to BLₙ₋₁. The word line WL₀ is connected to control gates of first memory cell transistors MT₀ connected to the bit lines BL₀ to BLₙ₋₁. A control line SGS is connected to gates of selection gate transistors STS connected to the source line SL. The control line SGD, the word lines WL₀ to WLₘ₋₁, the control line SGS and the source line SL respectively intersect with the bit lines BL₀ to BLₙ₋₁. The bit lines BL₀ to BLₙ₋₁ are connected to a sense amplifier (not shown in the drawing).

The selection gate transistors STD of the plurality of unit memory cells UC disposed in the row direction have gate electrodes thereof electrically connected with each other by the control line SGD. In the same manner, the selection gate transistors STS of the plurality of unit memory cells UC disposed in the row direction have gate electrodes thereof electrically connected with each other by the control line SGS. Sources of the selection gate transistors STS are connected to the source line SL in common. The memory cell transistors MT₀ to MTₘ₋₁ of the plurality of unit memory cells UC disposed in the row direction have gate electrodes thereof electrically connected with each other by the word lines WL₀ to WLₘ₋₁.

The unit memory cells UC of respective memory cell blocks BLK are connected to one of the bit lines BL₀ to BLₙ₋₁ in common. Further, source lines SL of respective memory cell blocks BLK are connected with each other by a common source line CSL.

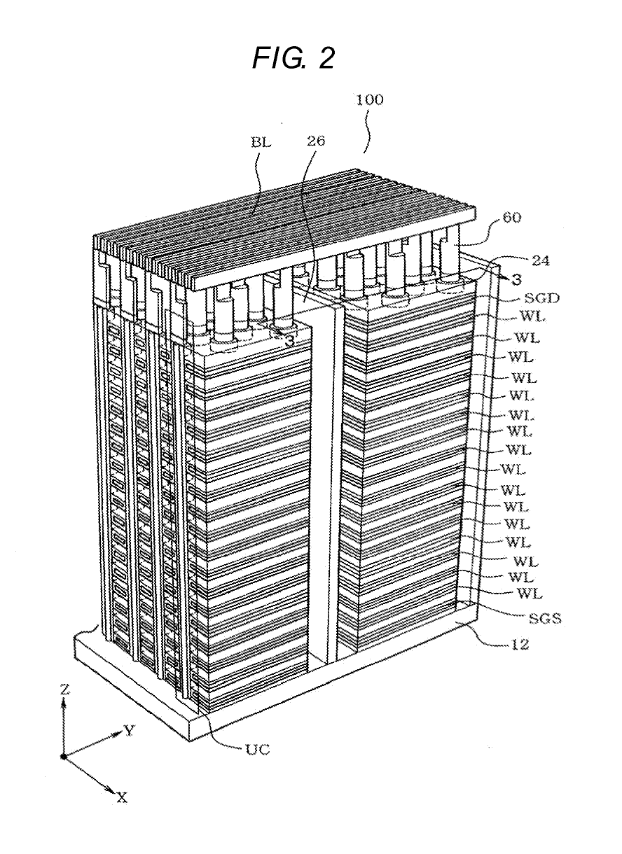

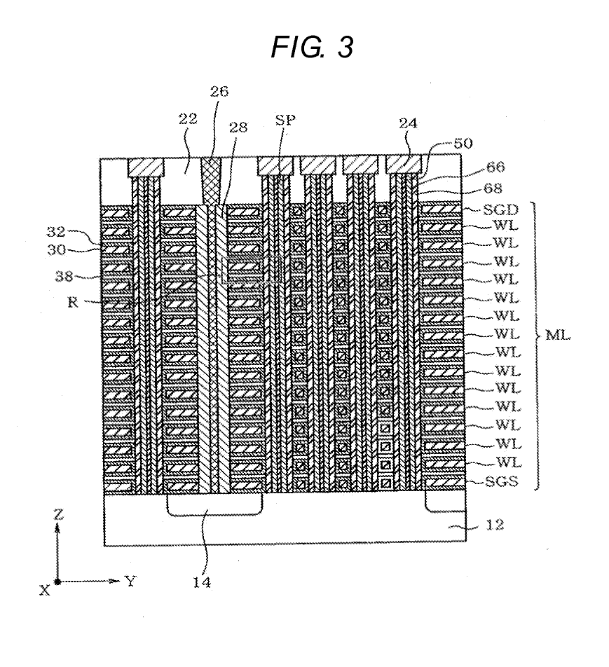

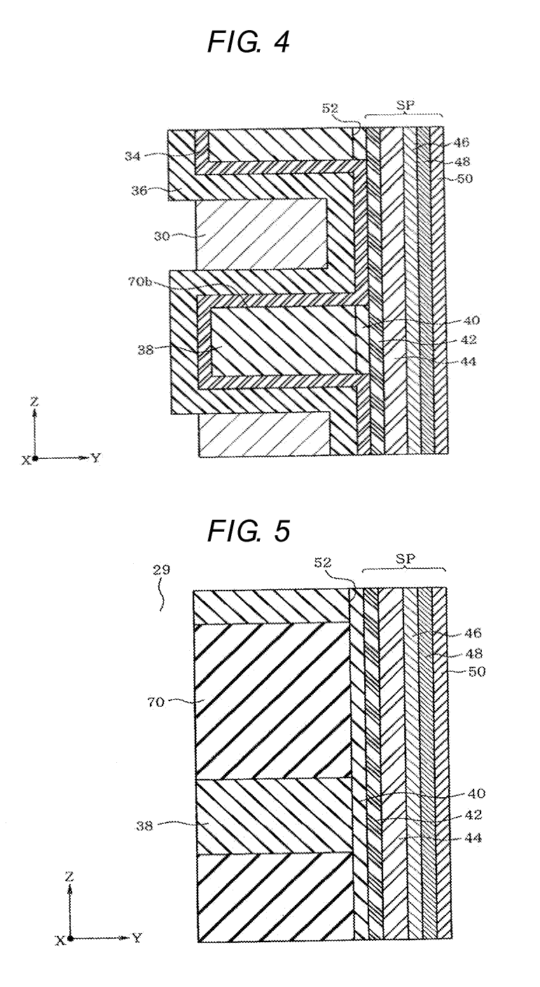

FIG. 2 illustrates a perspective view showing the configuration of a part of a memory cell region of the 3D-NAND-type flash memory device 100 according to this embodiment. To facilitate the understanding of the configuration, an inter-electrode insulation film 38, an interlayer insulation film 22 and the like are omitted. FIG. 3 illustrates a view showing a cross-section taken along a line 3-3 in FIG. 2. FIG. 4 illustrates an enlarged view showing a region R in FIG. 3.

As shown in FIG. 2, FIG. 3 and FIG. 4, a stacked structural body ML is formed on a semiconductor substrate 12. For example, a silicon substrate may be used as the semiconductor substrate 12. The stacked structural body ML includes a plurality of electrode films 30 and a plurality of inter-electrode insulation films 38 which are alternately stacked in the Z direction in the drawing. The electrode film 30 is formed using metal, for example. Tungsten may be used as metal, for example. A silicon oxide film may be used as the inter-electrode insulation film 38, for example.

Among the plurality of electrode films 30, the electrode film 30 disposed closest to the semiconductor substrate 12 is used as the selection gate electrode SGS on a source line side. The plurality of electrode films 30 above such an electrode film 30 are used as the word lines WL. The electrode film 30 which forms an uppermost layer is used as the selection gate electrode SGD on a drain side. The word lines WL, the selection gate electrode SGS and the selection gate electrode SGD respectively include the electrode film 30 and an insulation film 32 which is formed so as to surround the electrode film 30. The selection gate electrode SGS, SGD may be formed using a plurality of electrode films 30.

The insulation film 32 includes a second charge storage layer 34 and a block insulation film 36 in a stacked manner. The second charge storage layer 34 functions as a charge film, and also functions as a storage layer of a memory cell. A gate (gate electrode) of the memory cell transistor is formed of the electrode film 30 (word line WL). The block insulation film 36 functions as a block film. For example, a silicon oxide film may be used for forming the block insulation film 36. A film thickness of the electrode film 30 (a size of the electrode film 30 in the Z direction) becomes a length of a gate of the memory cell transistor where the electrode film 30 forms a gate electrode.

For example, a silicon-nitride film may be used for forming the second charge storage layer 34. It is possible to form the second charge storage layer 34 by using a film having a larger number of trap levels (trap sites) per unit volume than a first charge storage layer 42 (for example, a silicon-nitride film) (hereinafter simply referred to as a film having a large number of trap sites). A film having a large silicon composition ratio, that is, a silicon rich film, may be used for forming the second charge storage layer 34, where the second charge storage layer 34 has a higher silicon composition ratio than the first charge storage layer 42. A film thickness of the second charge storage layer 34 may be set smaller than a film thickness of the first charge storage layer 42.

Further, when the second charge storage layer 34 and the first charge storage layer 42 are formed of a silicon-nitride film, a refractive index of the second charge storage layer 34 is higher than a refractive index of the first charge storage layer 42, because, as noted above, the second charge storage layer 34 has a higher silicon composition ratio than the first charge storage layer 42. The second charge storage layer 34 may be doped with a dopant such as carbon thus forming a film having a large number of trap sites. The block insulation film 36 may be formed of a silicon oxide film, for example, and the number of trap sites in the block insulation film 36 is smaller than the number of trap sites in the second charge storage layer 34 and the first charge storage layer 42.

The interlayer insulation film 22 is formed on the stacked structural body ML. The interlayer insulation film 22 may be formed using a silicon oxide film, for example. Semiconductor pillars SP are formed in a state where the semiconductor pillars SP penetrate the stacked structural body ML and the interlayer insulation film 22 in the Z direction (the direction perpendicular to a surface of the semiconductor substrate 12), and a cap electrode 24 is mounted on the semiconductor pillar SP. The cap electrode 24 is formed of a metal film, for example, and tungsten may be used for forming the metal film, for example.

The cap electrode 24 is connected to the bit line BL via a contact electrode 60. A substrate contact 26 is formed in a state where the substrate contact 26 penetrates the stacked structural body ML and the interlayer insulation film 22 in the Z direction, and is connected to a doped region 14 formed on the semiconductor substrate 12. A slit insulation film 28 is formed in a state where the slit insulation film 28 surrounds the substrate contact 26 thus insulating the stacked structural body ML and the substrate contact 26 from each other. The slit insulation film 28 and the substrate contact 26 are disposed in an extending manner in the X direction thus dividing the stacked structural body ML in the X direction. The slit insulation film 28 may be formed using a silicon oxide film, for example. The substrate contact 26 may be formed using tungsten, for example.

The 3D-NAND-type flash memory device 100 includes the semiconductor pillars SP which penetrate the interlayer insulation film 22 and the stacked structural body ML in the Z direction. In the semiconductor pillar SP, a core insulation film 50, a second semiconductor film 48, a first semiconductor film 46, a tunnel insulation film 44 and a first charge storage layer 42 are formed in order from the center.

The core insulation film 50, the second semiconductor film 48, the first semiconductor film 46, the tunnel insulation film 44, and the first charge storage layer 42 are formed in a stacking manner in a hole which penetrates the stacked structural body ML and the selection gate electrodes SGD, SGS in the Z direction. In FIG. 3, the first semiconductor film 46 and the second semiconductor film 48 are indicated as a semiconductor film 66. Further, in FIG. 3, the first charge storage layer 42 and the tunnel insulation film 44 are indicated as an insulation film 68.

The semiconductor pillar SP has a cylindrical shape (for example, a circular cylindrical shape) or a columnar shape (for example, a circular columnar shape, where the diameter of the column varies along the length thereof) extending in the Z direction, for example. The first semiconductor film 46 and the second semiconductor film 48 of the semiconductor pillar ST form a channel portion of the transistor. The core insulation film 50 may be formed using a silicon oxide film, for example. The first semiconductor film 46 and the second semiconductor film 48 may be formed using amorphous silicon.

The tunnel insulation film 44 may be formed using a silicon oxide film, for example. The tunnel insulation film 44 functions as a tunnel film. The first charge storage layer 42 may be formed using a silicon-nitride film, for example. A center portion of the semiconductor pillar SP maybe hollow.

The first charge storage layer 42 extends along a side wall of the semiconductor pillar SP in the Z direction in the drawing (in the direction perpendicular to an upper surface of the semiconductor substrate 12), in a substantially straight-line shape. The first charge storage layer 42 is disposed to face the plurality of electrode films 30 (word lines WL). The first charge storage layer 42 is formed using a film having a smaller number of trap sites than the second charge storage layer 34. The first charge storage layer 42 is formed using a film having a smaller silicon composition ratio than the second charge storage layer 34. When the first charge storage layer 42 is formed of a silicon-nitride film of a lower silicon composition than that of the second charge storage layer 34, the first charge storage layer 42 exhibits a lower refractive index than the second charge storage layer 34.

The electrode films 30 disposed adjacent to each other are separated from each other in an insulating manner by the inter-electrode insulation film 38. In FIG. 2 and FIG. 3, the configuration where the electrode films 30 are formed in 16 layers is exemplified. However, the number of layers of electrode films 30 may be set as desired. The number of electrode films 30 is set to the number which is a multiple of 8 in many cases, for example. Further, a plurality of dummy layers may be formed above the electrode films 30, for example. The inter-electrode insulation film 38 may be formed using a silicon oxide film, for example.

The electrode film 30 has a strip shape extending along the X direction in the drawing (in the depth direction when viewing FIG. 3). The electrode film 30 forms the word line WL of the 3D-NAND-type flash memory device 100 according to this embodiment. The electrode film 30 may be formed using tungsten.

A plurality of second charge storage layers 34 and a plurality of block insulation films 36 are formed in a stacking manner in the Z direction in the drawing. The second charge storage layers 34 and the block insulation films 36 are continuously formed such that U-shapes thereof are alternately connected to a side surface of the electrode film 30 and the inter-electrode insulation film 38. The second charge storage layer 34 and the block insulation film 36 are each formed as one continuous layer. Between the electrode film 30 and the inter-electrode insulation film 38, the block insulation film 36 and the second charge storage layer 34 are formed from a side close to the electrode film 30.

The block insulation film 36 is brought into contact with the electrode film 30. The second charge storage layer 34 is brought into contact with the inter-electrode insulation film 38. Between the electrode film 30 and the first semiconductor film 46, the block insulation film 36, the second charge storage layer 34, the first charge storage layer 42 and the tunnel insulation film 44 are formed from a side close to the electrode film 30. The block insulation film 36 is brought into contact with the electrode film 30. The tunnel insulation film 44 is brought into contact with the first semiconductor film 46. That is, this embodiment exemplifies a MONOS (metal-oxide-nitride-oxide silicon) type NAND-type flash memory device as the 3D NAND type flash memory device 100.

The memory cell transistor (memory cell) is formed at a portion where the electrode film 30 and the semiconductor pillar SP intersect with each other. The first charge storage layer 42 and the second charge storage layer 34 which function as storage layers respectively are provided between the first semiconductor film 46 which forms a channel portion of the memory cell transistor and the electrode film 30. The memory cell transistors are thus disposed in a three-dimensional matrix configuration. Each memory cell transistor functions as a memory cell which stores information (data) by storing a charge in the storage layer. In each memory cell, the storage layer (the first charge storage layer 42 and the second charge storage layer 34) stores or discharges a charge in response to an electric field applied between the semiconductor pillar SP and the electrode film 30, and functions as a charge storage layer (information storage unit).

The interlayer insulation film 22 is formed on the selection gate electrode SGD. The bit lines BL are formed on the interlayer insulation film 22, and the bit lines BL are connected with the cap electrodes 24 via contact electrodes 60. The bit lines BL extend in the Y direction (the left and right direction in FIG. 3) and have a strip-like shape, for example. The interlayer insulation film 22 maybe formed using a silicon oxide film, for example.

The selection gate transistor is formed on portions where the selection gate electrodes SGD, SGS and the semiconductor pillar SP intersect with each other. The selection gate transistor functions as a MOS transistor where the block insulation film 36, the second charge storage layer 34, the first charge storage layer 42 and the tunnel insulation film 44 form a gate portion, and the first semiconductor film 46 and the second semiconductor film 48 form a channel portion. The memory cell transistors formed on one semiconductor pillar SP form a memory string. The selection gate electrodes STD, STS function as a switching transistor for selecting the memory string.

As has been explained heretofore, according to the 3D-NAND-type flash memory device 100 according to this embodiment, a film having a large number of trap sites is used for forming the second charge storage layer 34. Accordingly, an erasing characteristic of the memory cell is improved. In the case where the second charge storage layer 34 is formed using a silicon-nitride film, a refractive index is increased when a silicon composition ratio of the second charge storage layer 34 is large (that is, when the second charge storage layer 34 is rich in silicon so that the number of trap sites can be increased and the erasure characteristic thereof improved).

Although a film having a large number of trap sites is used for forming the second charge storage layer 34, the film having a large number of trap sites has a characteristic that a charge stored using the film as a path is more likely to move. Accordingly, when a film having a large number of trap sites is used as a charge storage layer of a memory cell, a charge moves using the film as a path and hence, there is a possibility that a data retention characteristic is deteriorated. That is, there is a possibility that a charge stored in a charge storage unit (information storage unit) of a certain memory cell moves to a charge storage unit (information storage unit) of the adjacent memory cell using the second charge storage layer 34 continuously formed with the charge storage unit as a path.

However, in the 3D-NAND-type flash memory device 100 according to this embodiment, the second charge storage layer 34 is formed in a shape where the U-shapes are connected to each other in a zig-zag manner. Accordingly, a moving distance of a charge which moves using the second charge storage layer 34 as a path is increased between the adjacent memory cell transistors. Accordingly, the data retention characteristic is enhanced. Further, a film thickness of the second charge storage layer 34 is set smaller than a film thickness of the first charge storage layer 42. Therefore, when a charge moves using the second charge storage layer 34 as a path, a width of the charge moving path becomes narrow and hence, the movement of a charge is suppressed. Accordingly, the data retention characteristic is enhanced.

### (Manufacturing Method)

Next, a method of manufacturing the 3D-NAND-type flash memory device 100 according to this embodiment is explained with reference to FIG. 4 to FIG. 8. FIG. 4 to FIG. 8 are cross-sectional views showing the steps of a method of manufacturing the 3D-NAND-type flash memory device 100 according to this embodiment in order, and are views schematically showing the cross-section taken along line 3-3 in FIG. 2.

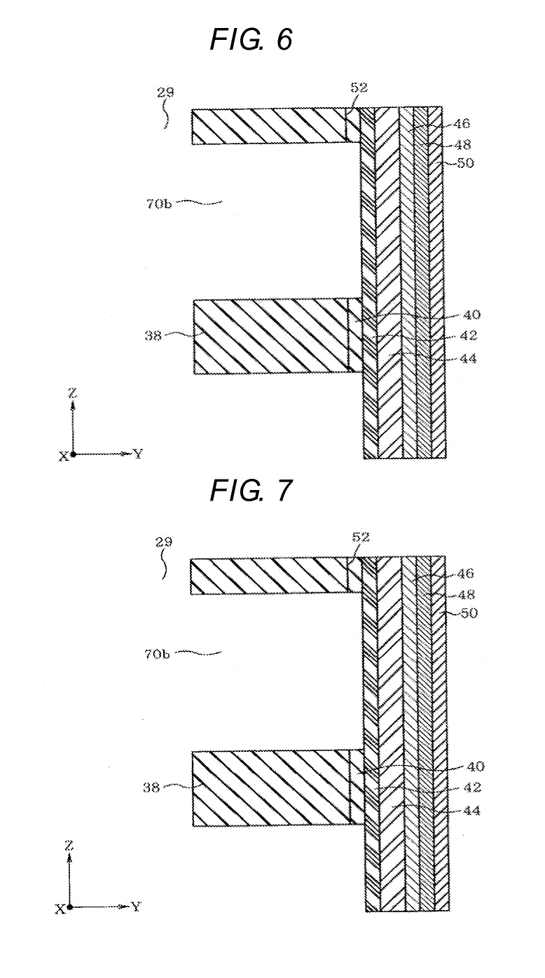

First, as shown in FIG. 5, the inter-electrode insulation film 38 and a sacrificial film 70 are alternately formed in plural layers respectively on the semiconductor substrate 12. The inter-electrode insulation film 38 may be formed using a silicon oxide film, for example. The silicon oxide film may be formed using a CVD (Chemical Vapor Deposition) method, for example. The sacrificial film 70 may be formed using a silicon-nitride film, for example. The silicon-nitride film may be formed using a CVD method, for example.

Next, a hole 52 is formed such that the hole 52 penetrates a stacked film formed by stacking the inter-electrode insulation films 38 and the sacrificial films 70 in the Z direction. The hole 52 may be formed using a lithography method, an RIE (Reactive Ion Etching) method, for example.

Next, the insulation film 40, the first charge storage layer 42, the tunnel insulation film 44 and the first semiconductor film 46 are formed in the hole 52 in order from the outside. The insulation film 40 may be formed using a silicon oxide film, for example. The silicon oxide film may be formed using a CVD method.

By forming the insulation film 40 in the form of a coarse film, an etching rate of the insulation film 40 is increased. That is, in etching described later, the difference in etching rates between the insulation film 40 and the inter-electrode insulation film 38 (both being formed of a silicon oxide film) is obtained and hence, the insulation film 40 maybe selectively etched.

The first charge storage layer 42 may be formed using a silicon-nitride film, for example. The silicon-nitride film may be formed using a CVD method, for example. The tunnel insulation film 44 may be formed using a silicon oxide film, for example. The silicon oxide film may be formed using a CVD method, for example. The first semiconductor film 46 may be formed using amorphous silicon, for example. Amorphous silicon may be formed into a film using a CVD method, for example.

Next, etching is performed by an RIE method using an anisotropic condition so as to remove the insulation film 40, the first charge storage layer 42, the tunnel insulation film 44 and the first semiconductor film 46 on a bottom portion of the hole 52 (not shown in the drawing). Subsequently, the second semiconductor film 48 is formed. The second semiconductor film 48 may be formed using amorphous silicon. Amorphous silicon may be formed into a film using a CVD method, for example.

Next, the core insulation film 50 is formed such that the hole 52 is filled with the core insulation film 50. The core insulation film 50 may be formed using a silicon oxide film. The silicon oxide film may be formed using a CVD method, for example. Next, a slit 29 is formed in an extending manner in the X direction in the drawing such that the slit 29 divides the stacked film formed of the inter-electrode insulation films 38 and the inter-electrode insulation films 38.

Next, as shown in FIG. 6, grooves 70b are formed by removing the sacrificial films 70. The grooves 70b may be formed by using treatment as follows. That is, the sacrificial films 70 are removed by etching using a hot phosphoric acid as a wet etchant, for example. Etching using a hot phosphoric acid has an etching selection ratio for a silicon oxide film and hence, etching is temporarily stopped when a surface of the insulation film 40 is exposed.

Next, the exposed insulation film 40 is removed by etching using, for example, a diluted hydrofluoric acid solution as a wet etchant. A diluted hydrofluoric acid solution has a selection ratio for a silicon-nitride film and hence, etching is stopped when a surface of the first charge storage layer 42 is exposed. Due to such steps, the groove 70b is formed.

As described previously, the insulation film 40 is formed as a film having a larger etching rate than the inter-electrode insulation film 38. Accordingly, the inter-electrode insulation film 38 is not etched so much during etching the insulation film 40. A wet etchant maybe supplied through the slit 29 formed for forming the substrate contact 26 and the slit insulation film 28.

Next, as shown in FIG. 7, the second charge storage layer 34 and the block insulation film 36 are sequentially formed on the whole surface including the inside of the groove 70b. The second charge storage layer 34 may be formed using a silicon-nitride film, for example. The silicon-nitride film maybe formed using a CVD method, for example. During forming the silicon-nitride film, a film forming condition is adjusted such that a silicon-rich film is formed as the silicon-nitride film. For example, a silicon-rich silicon-nitride film may be formed as the silicon-nitride film by adjusting a ratio between dichlorosilane and ammonia when the silicon-nitride film is formed using dichlorosilane and ammonia. Due to such a step, the second charge storage layer 34 contains an amount of silicon larger than the first charge storage layer 42.

By forming the second charge storage layer 34 as a silicon-rich film in this manner, the formed silicon-nitride film becomes a film having a large number of trap sites. When a film having a large number of trap sites is used as a charge storage layer of a memory cell of a flash memory, an erasing characteristic is enhanced. Further, the number of trap sites is increased by injecting a dopant such as carbon into the second charge storage layer 34 by doping. The block insulation film 36 may be formed using a silicon oxide film. The silicon oxide film may be formed using a CVD method, for example.

Although the example is exemplified where the second charge storage layer 34 and the first charge storage layer 42 are formed using a silicon-nitride film, a metal oxide film such as a silicon oxynitride film (SiON) or a hafnium oxide film (HfO) may be used in place of a silicon-nitride film. Further, although the block insulation film 36 is formed using a silicon oxide film in the example, the block insulation film 36 maybe formed using an alumina film (AIO) or a silicon oxide film/alumina stacked film in place of a silicon oxide film.

Next, as shown in FIG. 8, the electrode film 30 is formed so as to cover a surface of the block insulation film 36. A conductive film may be used for forming the electrode film 30. The electrode film 30 may be formed using a metal film, for example. The metal film may be formed using tungsten, for example. The metal film made of tungsten may be formed using a CVD method, for example.

Next, as shown in FIG. 4, the electrode film 30 is retracted by applying etching back to the electrode film 30 thus embedding the electrode film 30 in the groove 70b. Etching back of the electrode film 30 may be performed using an RIE method under an isotropic condition, for example.

Then, the cap electrodes 24, the contact electrodes 60, the bit lines BL and the like are formed using a known technique (see FIG. 1) thus forming the 3D-NAND-type flash memory device 100 according to this embodiment.

As has been explained heretofore, in the 3D-NAND-type flash memory device 100 according to this embodiment, a film having a large number of trap sites is used for forming the second charge storage layer 34 and hence, an erasing characteristic of the memory cell is improved.

Further, the second charge storage layer 34 is formed in a shape where the U-shapes are connected to each other in a zig-zag manner. Accordingly, a moving distance of a charge which moves using the second charge storage layer 34 as a path is increased between the adjacent memory cells. Accordingly, the data retention characteristic is enhanced.

A two-layered film formed of the first charge storage layer 42 and the second charge storage layer 34 is adopted for forming the charge storage layer and hence, the data retention characteristic is enhanced compared to the case where the charge storage layer is formed using only one layer of the second charge storage layer 34 having a small number of trap sites, for example.

A film thickness of the second charge storage layer 34 may be set smaller than a film thickness of the first charge storage layer 42. By forming the second charge storage layer 34 in this manner, when a charge moves using the second charge storage layer 34 as a path, a width of the charge moving path becomes narrow and hence, the movement of a charge is suppressed. Accordingly, the data retention characteristic is enhanced.

A two-layered film formed of the first charge storage layer 42 and the second charge storage layer 34 is adopted for forming the charge storage layer. This is because the charge storage layer is required to have an adequate film thickness. When the charge storage layer is formed using only one layer of the second charge storage layer 34, it is necessary to form the second charge storage layer 34 having a large film thickness. However, compared to such a case, in this embodiment, a film thickness of the second charge storage layer 34 is made small and hence, the whole film thickness of the charge storage layer in the Z direction is made small. Accordingly, the manufacturing process is simplified while ensuring the required gate length, leading to a reduction in the manufacturing cost.

### Second Embodiment

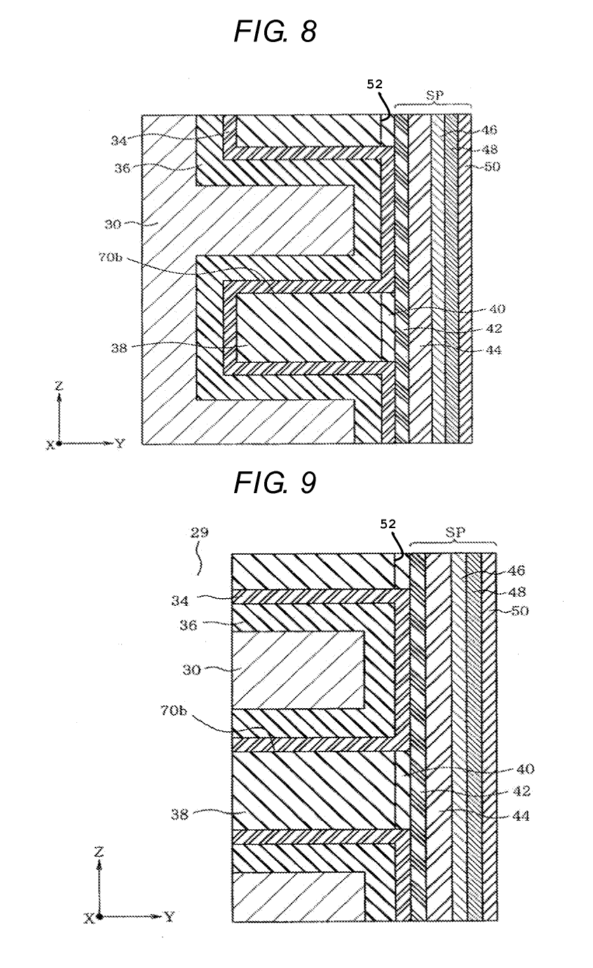

Next, the second embodiment is explained with reference to FIG. 9. In the explanation made hereinafter, elements having the identical functions and identical configurations as the elements explained in conjunction with the first embodiment are given the same symbols, and the explanation of these elements is omitted.

FIG. 9 is a cross-sectional view showing the structure of a 3D-NAND-type flash memory device 100 according to the second embodiment, and also provides an enlarged view of a region R shown in FIG. 3. The second embodiment differs from the first embodiment in that a second charge storage layer 34 and a block insulation film 36 are embedded in a groove 70b in a U shape independently. That is, assuming one U shape as a unit, the second charge storage layer 34 and the block insulation film 36 embedded in one groove 70b are not connected with the second charge storage layer 34 and the block insulation film 36 embedded in the adjacent groove 70b, and are independently formed from the second charge storage layer 34 and the block insulation film 36 embedded in the adjacent groove 70b. The second charge storage layer 34 is embedded in the individual grooves 70b independently, and is not connected with the second charge storage layer 34 in the adjacent groove 70b. The second charge storage layer 34 which functions as a charge storage layer of a memory cell which has one electrode film 30 as a gate electrode is independent from the second charge storage layer 34 which functions as a charge storage layer of an adjacent memory cell, and is not connected with the second charge storage layer 34 of the adjacent memory cell.

Due to such a configuration, a charge stored in the second charge storage layer 34 of one memory cell does not move to a charge storage unit (information storage unit) of the adjacent memory cell using the second charge storage layer 34 as a path. Accordingly, the data retention characteristic of the memory cell is enhanced.

Hereinafter, a method of manufacturing the 3D-NAND-type flash memory device 100 according to the second embodiment is explained. In the explanation made hereinafter, steps substantially the same as the steps of the manufacturing method of the first embodiment are omitted by using the drawings used in the first embodiment also in the second embodiment.

In the manufacturing method according to the second embodiment, firstly, the steps explained with reference to FIG. 4 to FIG. 8 in the first embodiment are performed. Next, as shown in FIG. 9, portions of electrode films 30, the second charge storage layers 34 and the block insulation films 36 which project from the inside of the grooves 70b are removed. The removal of the electrode films 30, the second charge storage layer 34 and the block insulation film 36 may be performed using a lithography method and an RIE method. In such a step, etching by an RIE method is performed under an anisotropic condition and hence, etching may be performed using the condition where the difference in etching rate is small among the electrode film 30, the second charge storage layer 34 and the block insulation film 36.

Next, cap electrodes 24, contact electrodes 60, bit lines BL and the like are formed using a known technique (see FIG. 1) thus forming the 3D-NAND-type flash memory device 100 according to this embodiment.

As has been explained heretofore, the 3D-NAND-type flash memory device 100 according to the second embodiment has the substantially same effects as the first embodiment. Further, the second charge storage layers 34 are divided and provided independently from each other such that the second charge storage layer 34 is embedded in each groove 70b. Accordingly, a charge stored in the second charge storage layer 34 does not move to a charge storage unit (information storage unit) of an adjacent memory cell using the second charge storage layer 34 as a path. Accordingly, the data retention characteristic of the memory cell is enhanced.

### Third Embodiment

The third embodiment is explained hereinafter. The drawings used for explaining the first embodiment and the drawings used for explaining the second embodiment are also used in the third embodiment in the similar manner. In the first embodiment or in the second embodiment, the second charge storage layer 34 is formed of a film having a larger number of trap sites than a film for forming the first charge storage layer 42. To the contrary, in the third embodiment, the first charge storage layer 42 is formed using a film having a larger number of trap sites than a film for forming the second charge storage layer 34.

That is, in the third embodiment, the first charge storage layer 42 is formed using a film having a larger silicon composition ratio (silicon-rich) and a higher refractive index than a film used for forming the second charge storage layer 34. The first charge storage layer 42 may be formed using a silicon-nitride film, and the first charge storage layer 42 may be formed using a CVD method in the same manner as the first and second embodiments. Also with respect to a method of adjusting the concentration of silicon, in the same manner as the first and second embodiments, it is possible to form a film having a large silicon composition ratio by adjusting a ratio between dichlorosilane and ammonia.

According to a 3D-NAND-type flash memory device 100 according to the third embodiment, the charge storage layer of the memory cell is formed using a film with a large number of trap sites. Accordingly, an erasing characteristic of the memory cell is enhanced.

The charge storage layer formed between a gate electrode and a channel electrode is formed of a stacked film which is formed of the film having the small number of trap sites (second charge storage layer 34) and the film having a large number of trap sites (first charge storage layer 42) and hence, a data retention characteristic is enhanced compared to a case where the charge storage layer is formed of a single-layered film having a large number of trap sites.

By setting a film thickness of the first charge storage layer 42 smaller than a film thickness of the second charge storage layer 34, the movement of a charge between adjacent memory cells using the first charge storage layer 42 as a path is suppressed. Accordingly, the data retention characteristic is enhanced.

### Other Embodiments

In the above-mentioned embodiments, one example is described where the present disclosure is applied to the NAND-type flash memory device. However, besides the NAMD-type flash memory device, the present disclosure is also applicable to a NOR-type flash memory device, a non-volatile semiconductor storage device such as an EPROM, a semiconductor storage device such as a DRAM, a SRAM or the like, or a logic semiconductor device such as a microcomputer.

In the above-mentioned embodiments, one example is described where the present disclosure is applied to the 3D-NAND-type flash memory device. However, the present disclosure is not limited to such an example, and the present disclosure is applicable to a planar NAND-type flash memory device in which memory cells are formed on a silicon substrate.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A non-volatile semiconductor storage device comprising:
a plurality of gate electrodes stacked in a first direction;
a channel portion facing the gate electrodes and extending in the first direction; and
first and second charge storage layers between the gate electrodes and the channel portion in a second direction crossing the first direction, wherein
the second charge storage layer has portions that are between the gate electrodes in the first direction.

2. The device according to claim 1, wherein
the first charge storage layer has no portion that is between the gate electrodes in the first direction.

3. The device according to claim 1, further comprising:
a semiconductor substrate above which the gate electrodes are stacked, wherein
the first direction is perpendicular to a surface of the semiconductor substrate.

4. The device according to claim 1, wherein
the second charge storage layer has a larger number of trap sites per unit volume than the first charge storage layer.

5. The device according to claim 1, wherein
the second charge storage layer has a larger composition ratio of silicon than the first charge storage layer.

6. The device according to claim 1, wherein
the second charge storage layer has a higher refractive index than the first charge storage layer.

7. The device according to claim 1, wherein
the first charge storage layer has a larger number of trap sites per unit volume than the second charge storage layer.

8. The device according to claim 1, wherein
the first charge storage layer has a larger composition ratio of silicon than the second charge storage layer.

9. The device according to claim 1, wherein
the first charge storage layer has a higher refractive index than the second charge storage layer.

10. The device according to claim 1, wherein
the second charge storage layer has a smaller film thickness than the first charge storage layer.

11. The device according to claim 1, wherein
the first charge storage layer comprises a silicon-nitride film.

12. The device according to claim 1, wherein
the second charge storage layer comprise a silicon-nitride film.

13. The device according to claim 1, further comprising:
an insulation film between the gate electrodes and the first and second charge storage layers, wherein
the insulation film has a smaller number of trap sites per unit volume than either the first or second charge storage layers.

14. The device according to claim 13, wherein
the insulation film comprises a silicon oxide film.

15. The device according to claim 1, wherein
the second charge storage layer has a zig-zag shape.

16. The device according to claim 15, wherein
the first charge storage layer has a straight-line shape extending in the first direction.

17. The device according to claim 16, wherein
the second charge storage layer is continuous from above the stack of gate electrodes to below the stack of gate electrodes.

18. The device according to claim 16, wherein
the first charge storage layer is formed of multiple portions that each have a U shape and are disconnected from each other.

19. A method of manufacturing a non-volatile semiconductor storage device comprising:
forming a first insulation film and a sacrificial film alternately in plural layers above a semiconductor substrate;
forming a hole through the plural layers in a first direction that is substantially perpendicular to a surface of the semiconductor substrate;
forming a first charge storage layer, a tunnel insulation film, and a semiconductor film in the hole;
removing the sacrificial film by etching to form recesses between the layers of the first insulation film;
sequentially forming a second charge storage layer, a second insulation film and then an electrode film in the recesses.

20. The method according to claim 19, further comprising:
removing portions of the electrode film, the second insulation film, and the second charge storage layer that project outwardly of the recesses.
